(19) United States
(12) Patent Application Publication
(10) Pub. No.: US 2025/0164392 A1
(43) Pub. Date: May 22, 2025

(54) Tunable laser spectroscopy system with gas line resolution

(71) Applicant: KineoLabs, Inc., Billerica, MA (US)

(72) Inventors: Walid A. Atia, Jamaica Plain, MA (US); Dale C. Flanders, Lexington, MA (US)

(21) Appl. No.: 18/947,498

(22) Filed: Nov. 14, 2024

Related U.S. Application Data
(60) Provisional application No. 63/599,580, filed on Nov. 16, 2023.

(51) Int. Cl. G01N 21/39; H01S 5/00

(52) U.S. Cl. CPC G01N 21/39; H01S 5/0085; G01N 2021/391; G01N 2201/06113; G01N 2201/0691

(57) ABSTRACT

A spectroscopy system and method enhance the resolution of narrow spectral features by modulating the injection current of a gain chip in a tunable laser. The system includes a tunable laser with an external cavity formed between the gain chip and an external reflector, containing a wavelength-selective element like a tilt-tuned interference filter. An oscillator drive signal modulates the injection current at high frequency and amplitude, altering the effective optical length of the external cavity and shifting the cavity modes over a range sufficient to resolve narrow spectral lines. This modulation ensures effective interaction with narrow absorption features in the sample. Operating at frequencies above the detector's bandwidth allows averaging over the modulation, reducing noise and improving signal quality. This technique is particularly beneficial for low-pressure gas spectroscopy, enabling precise detection and analysis of specific species within a sample.

### RELATED APPLICATIONS

This application claims the benefit under 35 USC 119 (e) of U.S. Provisional Application No. 63/599,580, filed on Nov. 16, 2023, which is incorporated herein by reference in its entirety.

### BACKGROUND OF THE INVENTION

Absorption spectroscopy measures the presence and/or concentration of a species of interest in a sample by passing a light beam through the sample and detecting the absorption at wavelengths of a particular spectral absorption feature of the species of interest. Generally, such a feature is an absorption line that represents the frequency of light corresponding to vibrational, rotational or electronic transitions of molecules of the gas or liquid of interest. Tunable narrow band sources such as lasers provide many advantages for such absorption spectroscopy measurements in that the lasers can be tuned to the center of a spectral feature and generate a narrow spectral signal relative to the width of the spectral feature.

Laser absorption spectroscopy can thus offer high speed and relatively high precision capabilities for detecting a variety of species in gas or liquid samples. Tunable diode laser spectrometers are particularly suited to high sensitivity studies, in part, because they may be frequency-modulated to reduce low frequency laser noise and electronic noise. In general, a laser spectrometer will include a frequency tunable laser that generates an illumination output beam which is directed through a sample cell that contains a sample. The output beam is then directed to an optical detector and the signal of the optical detector is demodulated to obtain an absorption induced signal. This absorption induced signal can be used to identify one or more species of interest within the sample and otherwise determine the constitutes of the sample.

Nevertheless, resolving gas lines, especially for low pressure gases, with tunable laser spectrometers presents several challenges. The precision and stability required for accurately resolving spectral lines demand sophisticated instrumentation and precise calibration, which can be challenging to maintain consistently. Additionally, environmental factors like temperature and pressure variations can affect the accuracy of measurements, necessitating precise control and compensation.

### SUMMARY OF THE INVENTION

The present invention concerns a tunable or swept laser architecture that is appropriate for applications including low pressure gas spectroscopy.

The swept laser employs a cat's-eye configuration with a preferably transmissive tilt tuned interference filter.

A spectroscopy systems' oscillator drive signal provides for narrow gas line resolution.

The present invention introduces an advanced spectroscopy system and method designed to enhance the resolution of narrow spectral features, particularly beneficial in applications such as low-pressure gas spectroscopy. Traditional tunable laser spectroscopy systems often struggle to resolve fine spectral lines due to limitations in spectral resolution and modal noise. This invention addresses these challenges by implementing a modulation technique that effectively shifts the cavity modes of a tunable laser over a sufficient range, ensuring that the laser output interacts with the narrow spectral features of interest.

A tunable laser configured to generate a laser output beam that illuminates the sample under investigation. This laser comprises a semiconductor gain chip, preferably a single angled facet (SAF) edge-emitting gain chip, which produces amplified light in response to an injection current supplied to it. The gain chip forms one end of an external cavity, with its reflective surface acting as the rear mirror. The other end of the cavity is defined by an external reflector, such as a partially reflective mirror serving as an output coupler. Within this external cavity lies a wavelength-selective element, typically a tilt-tuned interference filter, which selects the lasing wavelength by allowing only specific wavelengths to resonate within the cavity. The cavity modes are defined by the optical length of the external cavity, leading to specific cavity mode spacings.

To sweep the lasing wavelength over a desired scan range, an angle control actuator, such as a galvanometer or servomotor, adjusts the angle of the wavelength-selective element relative to the beam path within the external cavity. By tilting the interference filter, the passband shifts, allowing the laser to scan across different wavelengths. This tuning mechanism enables the interrogation of various spectral features of the sample by changing the lasing wavelength systematically.

A pivotal innovation of this invention lies in the modulation of the injection current supplied to the gain chip. A modulation circuit applies an oscillator drive signal to the injection current input of the gain chip. This oscillator drive signal possesses a frequency and amplitude sufficient to modulate the effective optical length of the external cavity. Modulating the injection current alters the carrier concentration and temperature within the gain chip, leading to changes in the refractive index of the gain medium. Consequently, this variation affects the optical length of the cavity, causing the cavity modes to shift in wavelength.

By carefully selecting the frequency and amplitude of the oscillator drive signal, the cavity modes shift over a range corresponding to at least one cavity mode spacing. Preferably, the modulation induces a phase change of at least 2π radians at the lasing wavelength. This effect effectively “smears” the cavity modes across the narrow spectral features of the sample. As a result, even if the spectral lines are narrower than the cavity mode spacing, the modulated laser output interacts with them, enhancing the spectral resolution of the system.

The oscillator drive signal operates at a high frequency, typically greater than 1 kilohertz (kHz), and more preferably greater than 1 megahertz (MHz). By modulating at a frequency higher than the detection bandwidth of the detector, the detector averages over the modulation, providing a smooth absorption-induced signal without introducing high-frequency noise. This approach also reduces modal noise associated with multimode operation, improving the signal-to-noise ratio of the detected signal.

After passing through the sample, which may be a low-pressure gas or any medium with narrow spectral features, the laser output beam is detected by a detector configured to capture the absorption-induced signal. The detected signal is then processed to determine the presence and concentration of specific species within the sample. This modulation technique ensures that the laser output effectively interacts with the narrow absorption lines, allowing for precise identification and quantification of the sample constituents.

One of the significant advantages of this invention is its compatibility with existing tunable laser architectures. The modulation circuit can be integrated into current systems with minimal modifications, making it a versatile solution for enhancing spectral resolution in various spectroscopy applications. This includes fields such as chemical sensing, environmental monitoring, medical diagnostics, and any other area where high-resolution spectroscopy is essential.

Furthermore, the invention encompasses a method for spectroscopy that involves generating laser light with a tunable laser comprising a gain chip and an external cavity with a wavelength-selective element. The method includes modulating the injection current to the gain chip with an oscillator drive signal to vary the effective optical length of the external cavity, thereby shifting the cavity modes. The modulated laser light is directed through a sample, and the absorption-induced signal is detected and processed to resolve narrow spectral features and determine the characteristics of the sample.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIGS. 1 and 2 are perspective views of a spectroscopy system according to the present invention;

FIG. 3 shows the electro optics of the spectroscopy system including the tunable laser and sample detector along with reference detectors;

FIGS. 4 and 5 are schematic side views of a cat's-eye tunable laser with its oscillator drive system;

FIG. 5 is a plot of the laser frequency, angle of the angle control actuator 50, power set point reference signal 250, error signal feedback control of the oscillator drive signal;

FIG. 6 is plot showing the relationship between different cavity modes and the filter's passband;

FIG. 7 is plot showing low pressure gas line resolution, low pressure being ambient pressure up to 50 psi, or higher to 100 psi; and

FIGS. 8A and 8B are plots showing the oscillator drive signal.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Also, all conjunctions used are to be understood in the most inclusive sense possible. Thus, the word “or” should be understood as having the definition of a logical “or” rather than that of a logical “exclusive or” unless the context clearly necessitates otherwise. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

It will be understood that although terms such as “first” and “second” are used herein to describe various elements, these elements should not be limited by these terms. These terms are only used to distinguish one element from another element. Thus, an element discussed below could be termed a second element, and similarly, a second element may be termed a first element without departing from the teachings of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

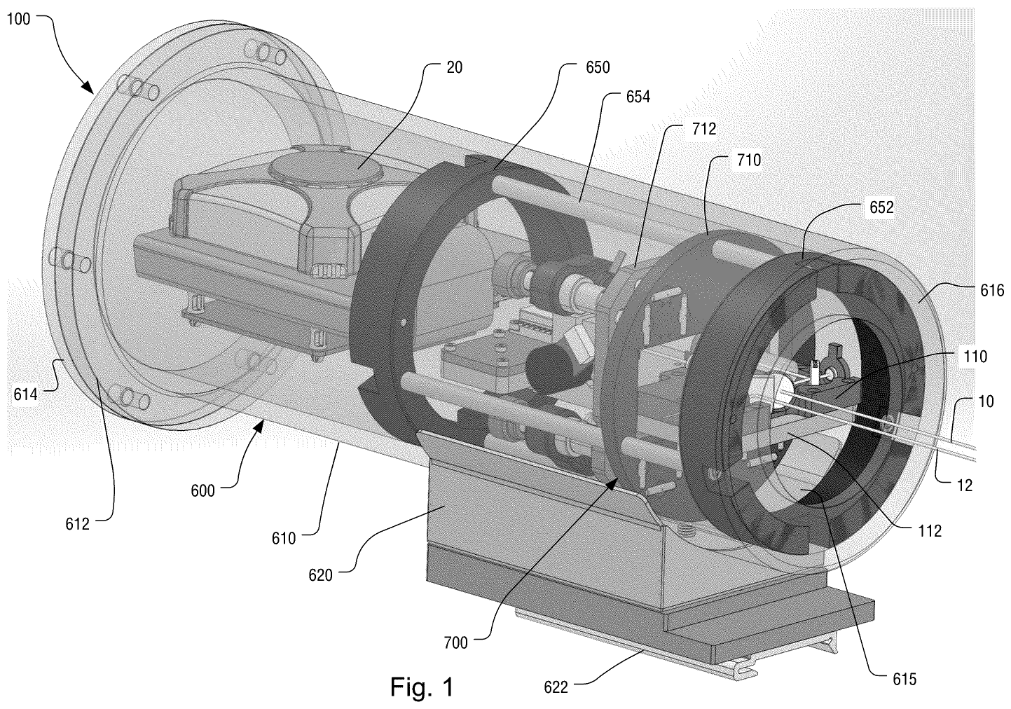

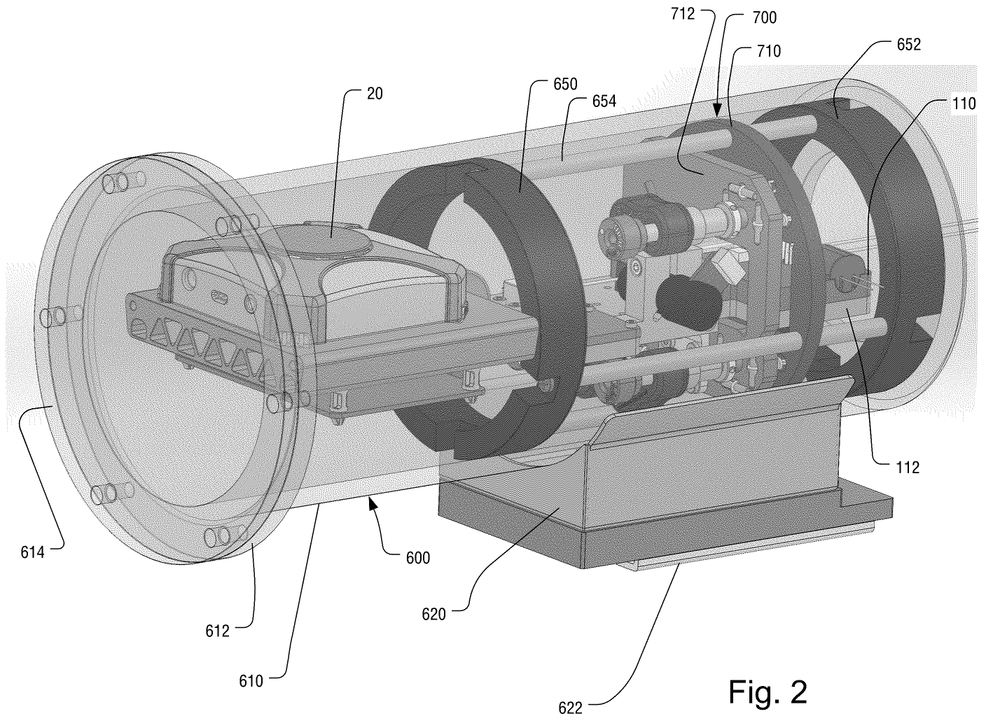

FIGS. 1 and 2 show a spectroscopy system 100 to which the present invention is applicable in a specific example.

The spectroscopy system includes an optional explosion proof enclosure 600 shown in phantom. In the illustrated example, the explosion proof enclosure 600 is generally tubular in shape and often fabricated from metal such as stainless steel or aluminum. At the back end, an enclosure flange 612 that mates to a blind flange 614. The two flanges are typically secured to each other using a series of bolts not shown. The front part of the enclosure includes a front ring 616 that is integral to the tubular section of the enclosure housing 610. The front ring 616 holds a transmissive enclosure front window 615. Such explosion proof enclosures 600 are helpful when monitoring explosive gases such as methane.

The illustrated example also includes an enclosure coupling 620 that cradles the enclosure housing 610. It can be welded to the housing or attached using metal hose clamps. In the illustrated example, the enclosure coupling 620 is used to mount the spectroscopy system 100 to a support such as the illustrated mounting rails 622.

The electro optical components of the spectroscopy system 100 are inserted into the explosion proof enclosure 600 typically by removing the blind flange 614 at the rear and inserting those components into the hollow interior of the enclosure housing 610.

In more detail, a rear mounting ring 650 and a front mounting ring 652 center the components in the housing's internal bore. A series (such as the four shown) of ring standoffs 654 connect the rear mounting ring 650 and the front mounting ring 652.

Supported on the standoffs 654 is a bench kinematic mount 700. Specifically, a kinematic base 710 is held by the four ring standoffs 654.

A kinematic platform 712 is supported by the kinematic base 710 in the style of a typical kinematic mount such that it can be tilted in each of two spatial axes. This is used to change the angle of an optical base bench 112 that is supported on the kinematic platform 712 in the manner of a cantilever. By controlling the angle of the optical base bench 112 relative to the explosion proof enclosure 600, the direction of an output beam 10, that illuminates a sample contained in a flow cell, for example, is controlled. In addition, in the illustrated transflection arrangement, a return beam 12 is also guided such that it is coupled to a sample detector, also held by the optical base bench 112.

Also in the explosion proof enclosure 600 is a controller system 20. This includes a digital processor, digital to analog converters and analog to digital converters for both controlling the spectrometer and monitoring the spectrometer in order to resolve the absorption spectra of a sample being analyzed.

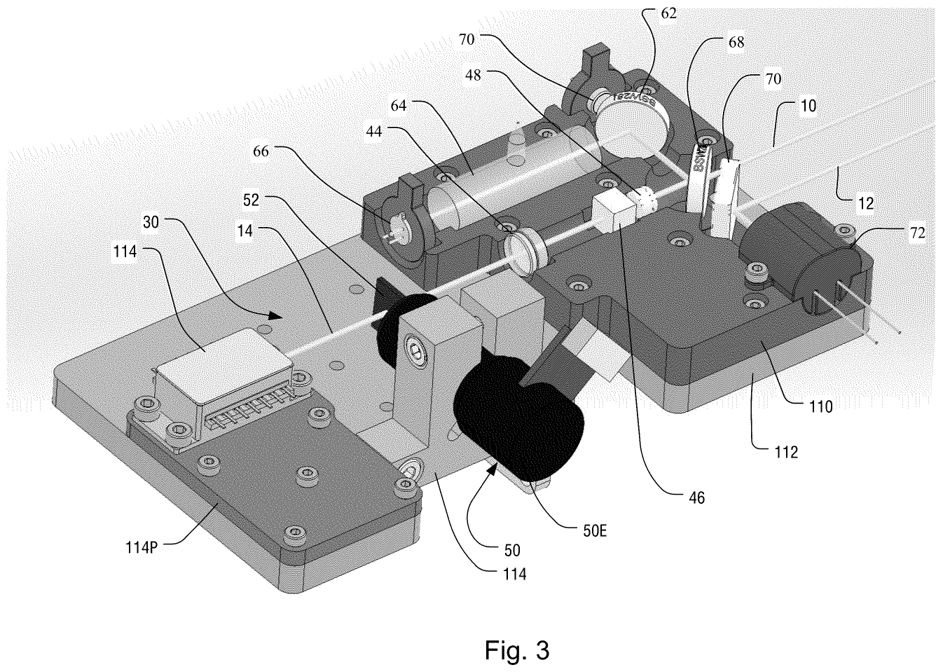

FIG. 3 shows a tunable laser 30 and detectors 66, 70, and 72 and the manner of their construction packaging.

Mounted on the base bench 112 is a package pedestal 114P and an optical upper bench 110. The benches and pedestal are often 3D printed using a filament-fed, FDM 3D printer or a MSLA (Masked Stereolithography) resin 3D printer. In other examples these benches and pedestal are fabricated from metal such as machined aluminum.

A package 114 is mounted to the package pedestal 114P and contains a collimation and optical gain assembly. The laser's amplification is provided by an InP gain chip in the illustrated butterfly package 114 or other hermetic enclosure. This package protects the chip from dust and the ambient environment including moisture. In some examples, the package 114 has an integrated or a separate thermoelectric cooler. In the current example, a lens is also installed in the package 114 to collimate the light emission from the gain chip to yield the collimation and optical gain assembly.

Other material systems can be selected for the gain chip 115 beside InP, however. Common material systems are based on III-V semiconductor materials, including binary materials, such as GaN, GaAs, InP, GaSb, InAs, as well as ternary, quaternary, and pentenary alloys, such as InGaN, InAlGaN, InGaP, AlGaAs, InGaAs, GaInNAs, GaInNAsSb, AlInGaAs, InGaAsP, AlGaAsSb, AlGaInAsSb, AlAsSb, InGaSb, InAsSb, and InGaAsSb. Collectively, these material systems support operating wavelengths from about 400 nanometers (nm) to 2500 nm, including longer wavelength ranges extending into multiple micrometer wavelengths. Semiconductor quantum well, quantum cascade and quantum dot gain regions are typically used to obtain especially wide gain and spectral emission bandwidths, and support operation up to 250 μm in wavelength, or more. Quantum well layers may be purposely strained or unstrained depending on the exact materials and the desired wavelength coverage.

In one example, the gain chip 115 amplifies light in the wavelength range of about 1500-1800 nanometers. The preferred chip architecture is termed a single angled facet (SAF) edge-emitting chip. As such, it has a high reflectivity (HR) coated rear facet. It has an antireflective (AR) coated front facet. In addition, for improved performance, it has a curved ridge waveguide that is perpendicular to the rear facet but is angled at the interface with the front facet. This angling at the front facet along with the AR coating reduces reflections at the front facet reflectivity by up to 40 dB and significantly improves laser performance by reducing parasitic reflections that can otherwise lead to non-smooth tuning and mode-hopping.

Preferably its center wavelength is around 1700 nanometers +/−50 nanometers, or more preferably +/−100 nanometers.

The free space beam collimated beam 14 emitted through a front optical window of the package 114 is received by a cat's eye focusing lens 44, which focuses the light onto a cat's eye mirror/output coupler 46. This defines the other end of the laser cavity, extending between the mirror/output coupler 46 and the back/reflective facet of the gain chip in the package 114. Note that in most embodiments, cavity length is between 10 mm and 150 mm in length.

The collimated light between the collimating lens and the cat's eye focusing lens 44 passes through a bandpass interference filter 52 that is angle tuned in the beam by a tilt actuator such as a galvanometer 50.

In the present design, the free spectral range of the tunable filter 52 is preferably greater than 200 nanometer and is preferably over 300 nm such as about 350 nm.

The so-called effective refractive index of the tunable filter 52 is preferably greater than 1.50, and is ideally higher than 1.60, such as 1.65.

The passband for the filter is preferably between 1 and 3 nanometers (nm), and more narrowly between 1.5 and 2.5 nm, FWHM. In one design, it is 2 nm. But, in operation, linewidth narrowing (˜4×) reduces this in the laser cavity for the effective laser linewidth.

These general design parameters yield a large number of longitudinal modes under the envelope for the filter linewidth for a laser cavity length of 50 mm. In the preferred embodiment, there are at least 15 modes under the filter envelope and at least 5 modes for linewidth narrowed emission to 0.5nm. Ideally, there are at least 25 modes and possibly 37 modes or more and at least 7 modes to 10 or more modes for linewidth narrowed emission.

This is a large number of modes works well for low noise spectral analysis. And keep in mind that the larger the number of modes, the lower the modal noise (by sqrt (number of modes)).

The bandpass filter 52 is held on an arm of tilt actuator 50. This allows for tilting of the bandpass filter in the collimated beam to thereby tilt tune the filter and thus change the passband to thereby scan or sweep the wavelength of the swept laser 100.

In the illustrated example, the tilt actuator is a servo galvanometer. In other examples, the angle control actuator 50 is a servomotor or an electrical motor that continuously spins the bandpass filter 52 in the collimated beam 14. This allows for tilting of the bandpass filter 52 with respect to the collimated beam 14 to thereby tilt-tune the filter and thus change the passband to scan or sweep the wavelength of the swept laser.

Tuning speed specifications for galvanometer generally range from 0.1 Hz to 50 KHz. For the higher speeds, a 25 kHz resonant galvo can be used with bi-directional tuning, but higher and lower speeds can be used. Wavelength tuning speed is usually given in nm/sec. In general, the tuning speed should be between 3000 nm/sec 11000 nm/sec.

The size of the collimated beam is important for many applications. As a general rule, a smaller beam results in higher divergence resulting in a larger cone half angle (CHA), which is the divergence of the beam hitting the tunable filter. This reduces the minimum line width over angle for a tunable filter. In the current embodiment, the CHA must be smaller than a given amount, typically 0.025 degrees, in order to maintain both linewidth and loss.

Note that a higher divergence beam has a smaller diameter, so this means we have to have collimated beams of a large enough diameter to provide the required maximum CHA, and larger beams require physically larger tunable filters. A beam size of ˜1 millimeters (mm) is typical for a CHA of 0.025 degrees, but because the beam from the chip is elliptical this should be chosen to be the smaller axis beam). Moreover, we can then choose the final output collimating lens that forms a telescope from the cat's eye focusing lens to have an output beam of whatever desired diameter we would like, with the magnification given by the ratio of the output lens focal length to the focusing lens focal length. Note that if desired the elliptical output beam is circularized with the use of anamorphic prism pairs, a pair of cylindrical lenses, or a simple spatial filter at the output, in different examples.

In any event, the beam size of beam 14 for the small axis at the tunable filter 52 is preferably between 0.5 and 2 mm.

The light from the gain chip 115 is polarized. In the common architectures, the polarization is horizontal or parallel to the epitaxial layers of the edge-emitting gain chip. In the preferred configuration, the filter is oriented to receive the S polarization in order to maintain narrow line width of the filter as it is tilt tuned. On the other hand, the P polarization broadens drastically at large tilt angles. S polarization has higher loss at larger tilt angles than P. So, the filter design needs to address these issues by providing a low enough loss across the tuning band for S.

In general, the present cat's-eye configuration provides a number of advantages. It provides low loss, low tolerance, repeatable stable operation since lower angle wavelength change over grating-based lasers.

The mirror/output coupler 46 will typically reflect less than 90% and preferably about 80% of the light back into the laser's cavity and transmits greater than 10% and preferably about 20% of light. Often, the transmitted light is collimated with the help of an output collimating lens 48. More generally, the mirror/output coupler can reflect from 10% to 99% of light (transmitting 90% to 1%, respectively), depending on the output power and laser cavity loss desired. Higher reflectivity results in lower loss cavities and thus wider laser tuning range where gain exceeds loss, but results in lower output power.

In some embodiments, an iris or mask is added typically after the output coupler to clip the beam edge. This reduces power fluctuations as the beam wanders due to refraction in the tilting bandpass filter.

The portion of the beam passing through the output coupler 46 is collimated by output collimating lens 48 and the collimated beam is typically received by output beamsplitter 68 that directs a portion of the beam to a reference beamsplitter 62. This divides the beam, such as a few percent to gas cell 64. After passage through the gas cell, the light is then detected by a gas cell detector 66. The transmitted light at the reference beamsplitter 62 is received by an amplitude reference detector 70.

The gas cell is employed for calibration for the detection of the same or similar gas by the system.

In other embodiments, the gas cell is replaced by a different gas cell. Currently, the system is intended to quantify the concentration of methane, so methane is contained in the gas cell, but other gases or mixtures of gases can be contained in the cell. In still another example, the gas cell is replaced with a stable wavelength reference such as an etalon.

For holding the various components, it has a series of cradles or V-groove optical element mounting locations formed into the top surface of the upper bench 110.

A galvanometer clamp 114 secures the galvanometer 50 to the optical base bench 110.

Finally, in the illustrated transflection arrangement, a sample detector 72 is further installed on the upper bench 110 to detect the output beam after being modulated by a sample such as a sample contained in a flow cell.

In the accompanying drawings, reference characters refer to the same parts throughout the different views. The drawings are not necessarily to scale; emphasis has instead been placed upon illustrating the principles of the invention. Of the drawings:

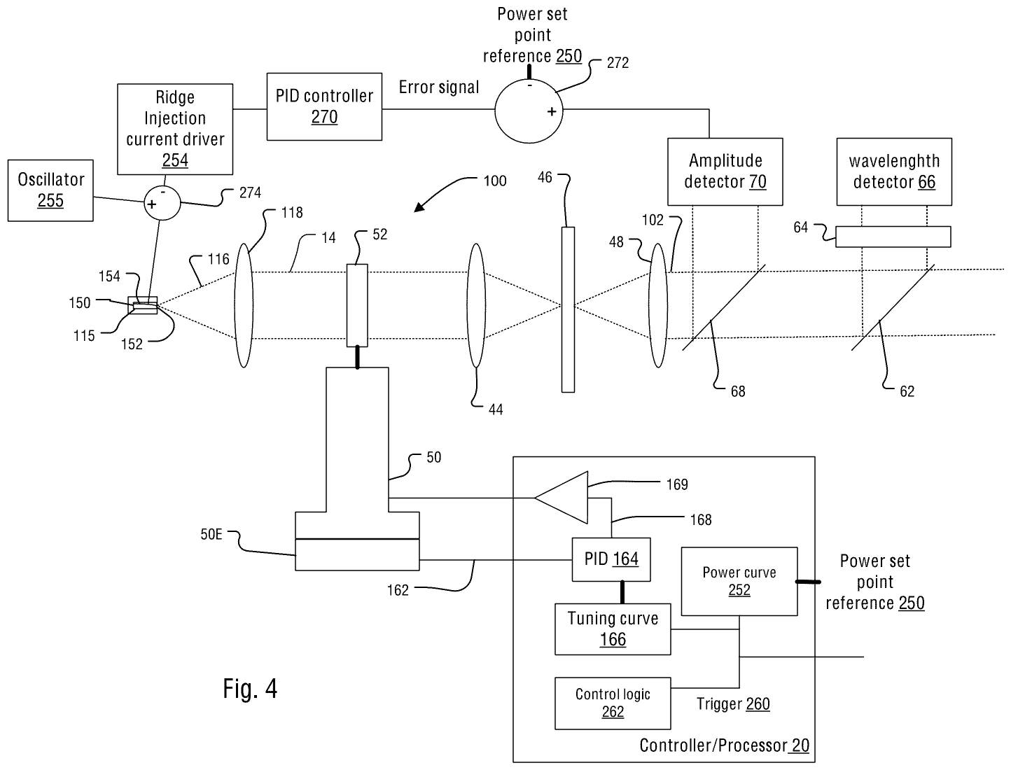

FIG. 4 shows the cat's-eye tunable laser 100 along with the electronics for driving the gain chip 115 and the galvanometer 50, which has been constructed according to the principles of the present invention.

The laser's amplification is provided by the gain chip 115, in one example. The gain chip 115 amplifies light. The chip 115 is preferably a single angled facet (SAF) edge-emitting chip. As such, it has a high reflectivity (HR) coated rear facet 150. It has an antireflective (AR) coated front facet 152. In addition, for improved performance, it has a curved ridge waveguide 154 that is perpendicular to the rear facet 150 but is angled at the interface with the front facet 152. This angling at the front facet along with the AR coating reduces reflections at the front facet reflectivity by up to 40 dB and significantly improves laser performance by reducing parasitic reflections that can otherwise lead to non-smooth tuning and mode-hopping.

The free space beam 116 is diverging in both axes (x, y). It is collimated by a collimating lens 118. The resulting collimated beam is received by a cat's eye focusing lens 44, which focuses the light onto a cat's eye mirror/output coupler 44. This defines the other end of the laser cavity, extending between the mirror/output coupler 46 and the back/reflective facet of the gain chip 115.

The collimated light 14 between the collimating lens 118 and the cat's eye focusing lens 44 passes through the thin film interference bandpass filter 52.

The bandpass filter is held on an arm of an angle control actuator 50 that changes the angle of the bandpass filter 52 to the collimated light 14. In one example, the angle control actuator is a galvanometer. In other examples, the angle control actuator 50 is a servomotor or an electrical motor that continuously spins the bandpass filter 52 in the collimated beam 14. This allows for tilting of the bandpass filter 52 with respect to the collimated beam 14 to thereby tilt-tune the filter and thus change the passband to scan or sweep the wavelength of the swept laser 100.

The angle control actuator 50 is operated as a servomechanism. In the illustrated embodiment, the angle control actuator 50 is a servo controlled galvanometer with an encoder 50E. The encoder 50E produces an angle signal 162 indicating the angle of the galvanometer and thus the filter 52 to the collimated beam 14. Preferably, the encoder is an optical encoder and is often analog.

The controller/processor 20 receives the angle signal 162 at a PID (proportional-integral-derivative) controller 164. The PID controller 164 compares the angle signal 164 to a specified tuning function stored in the tuning curve module 166. Often, the desired tuning curve is stored in a look up table or is generated algorithmically. Often, this is an approximately sawtooth or triangular waveform. The PID controller 164 produces the control function 168 that is used to drive the windings of the galvanometer 50 via an amplifier 169.

According to the invention, a portion, such as typically less than 10% of the output beam 10 is picked-off and directed by a beam splitter 68 to be detected by an amplitude detector 70. In this way, the power in the output beam 10 is monitored.

The wavelength detector 66 also samples the beam 10 through a wavelength reference 64, such as a gas cell.

The amplitude signal from the amplitude detector 70 is received at one terminal of a comparator 272. This is compared to a power set point reference signal 250 that is produced by a power curve module 252 in the controller processor 50. This power curve module 252 can produce the power reference 250 signal from a look up table or algorithmically in response to the trigger 260. This produces the error signal that is received by the PID controller 270 to control the ridge injection current driver 254.

An oscillator is further provided to add modulation on net DC injection current. The AC oscillator signal is combined with the injection current in a second comparator 274. In this way, the response of the amplitude detector is used to control the oscillator 255 and specifically the oscillator drive signal to the chip.

The depth of modulation, amplitude of the oscillator signal from oscillator 255 is selected to create a modulation of the optical length of the laser cavity. This effect is caused by increase in carrier concentration and change in temperature in the ridge waveguide of chip 115.

In general, the optical length change by the oscillator drive signal should be generally enough to shift the cavity modes spectrally overlap where a neighboring mode would have been. In general, the cavity mode spacing is c/2L, where c is the speed of light and L is the optical length of the cavity. Said another way, the optical length of the cavity needs to be modulated by a multiple of half a wavelength of the laser's wavelength of operation.

In the current example, the frequency of the oscillator signal is high, such as greater than 1 kHz. And preferably greater than 1 MHz. In one example, an analog averaging effect is employed in which the oscillator signal is greater than a bandwidth of the amplitude detector 70.

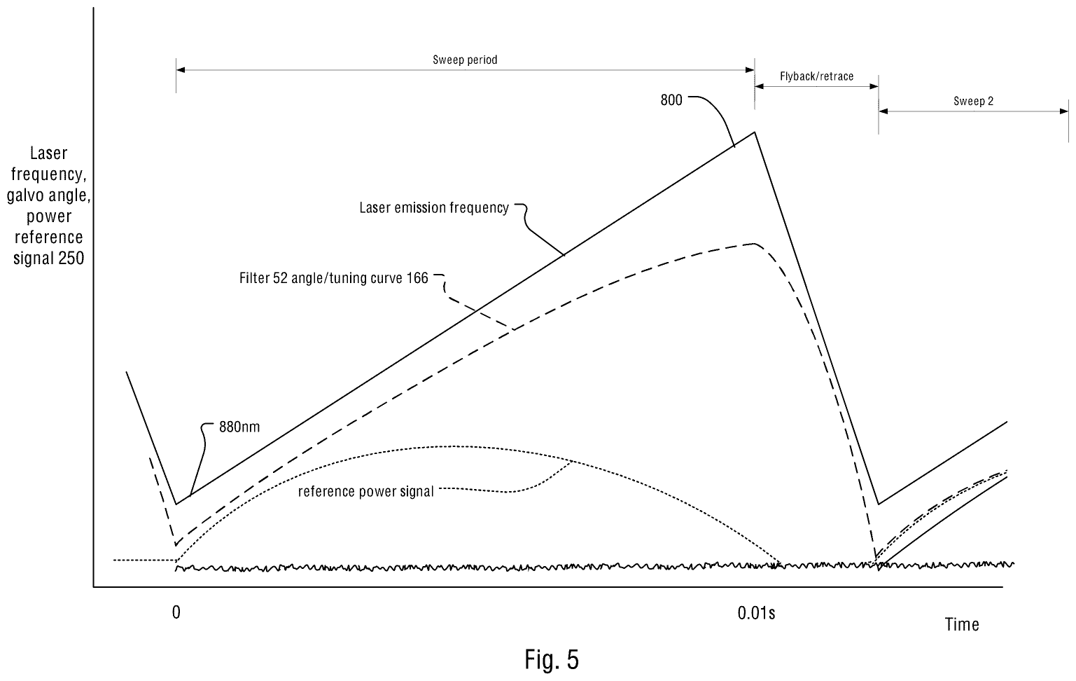

FIG. 5 is a plot of the laser frequency, angle of the angle control actuator 50, power reference set point signal 250, error signal for the collection of an absorption spectrum.

In more detail, the control logic 262 triggers the beginning of the scan with the trigger 260. The laser 100 is swept in wavelength so that its frequency changes preferably linearly with time over the sweep. A linear frequency sweep is often desirable but not necessary.

For the linear sweep in frequency, the angle of the filter 130 must be tuned in a non-linear fashion. As shown, the rate of change of the angle of the filter 130 slows with increasing angle and shorter wavelengths, higher frequency of the laser emission 102. This tuning curve for linear frequency sweeping is produced by and/or stored in the tuning curve module 166.

As the laser 100 begins its sweep, the control logic 262 of the controller-processor 50 generates the trigger signal that initiates the capturing of the line interference signals as the laser tunes.

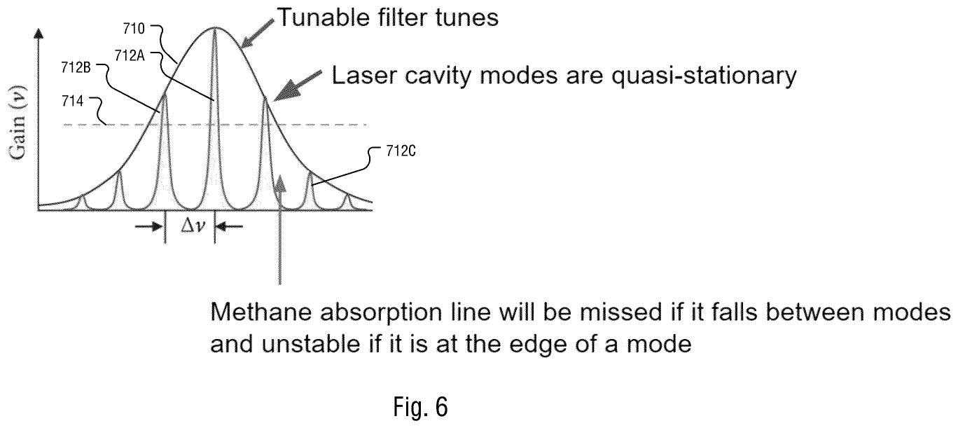

FIG. 6 illustrates the difficulty in resolving narrow gas lines with an external cavity tunable laser.

The laser cavity modes are set by the characteristics of the laser's cavity. Specifically, the optical length of the cavity sets the spacing of the cavity modes.

In more detail, the tilting of the filter 50 sweeps its passband 710 through the laser's scan band. Cavity modes 712A 712B that are above threshold 714 lase. Other modes 712C are suppressed. As the lasing modes 712A 712B interact with the narrow gas absorption lines, absorption is monitored by the sample detector 72. Nevertheless, the fine structure of the cavity modes 712 under the bandpass envelope 710 are effectively removed since their position is modulated due to the oscillator drive signal.

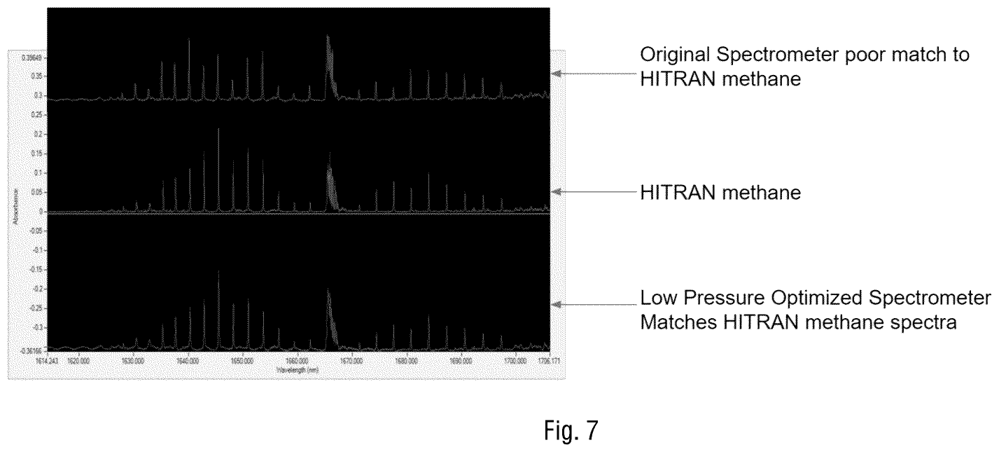

FIG. 7 shows a comparison of HITRAN methane data to the multi-longitudinal mode cat's eye tunable laser showing how the dither or oscillator drive signal (which is ˜100 kHz with amplitude from 0 to ˜200 mA), with sufficient averages (in this case 32 averages of 100 msec scans, so 3.2 seconds total) gives a nearly perfect match to the HITRAN spectra, whereas no dither misses the peaks due to the sharp methane lines not overlapping with the laser's cavity modes.

There also appears to be some relationship between the current dither amplitude and the chip temperature (as set by the TEC) that can make the match more perfect. Ideally, the phase change should be 2*PI(2π) or more so that the modes are smeared across the absorption lines, and there is a dependency on chip temperature and dither amplitude to get the right phase shift.

In addition, it is possible to have too much phase shift because it could be biased towards a wavelength and you want it to uniformly dither back and forth around a multiple of 2*PI.

Preferably, the dither amplitude is tailored to the sweep to approach 2*PI over the scan while the chip gain is changing.

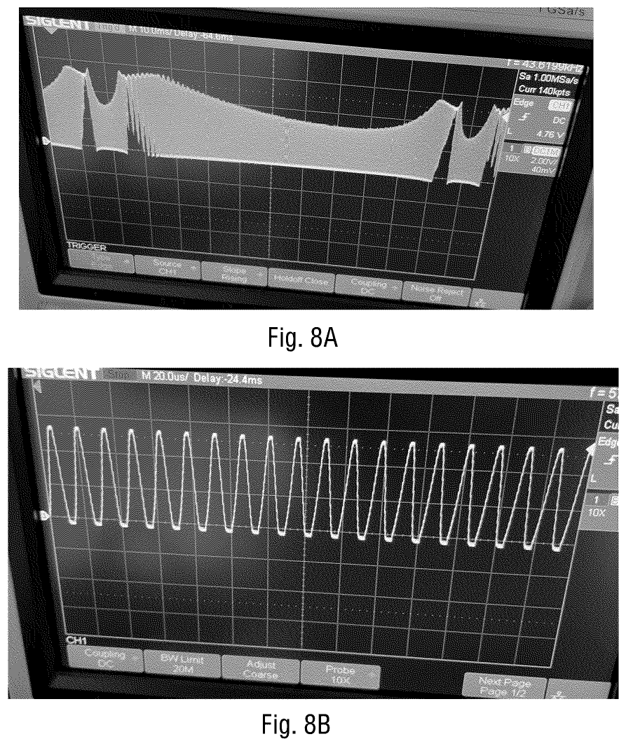

FIG. 8A and 8B show oscilloscope snapshots for the dither showing the amplitude and the frequency of the self-oscillating dither scheme.

FIG. 8A shows the overall shape of the current whereby the circuit is attempting to keep the power constant and as such traces the gain of the chip and hence the “U” shape where the gain is lowest at the edges and needs higher current to maintain the same power level. The fast “U” is due to the flyback where we could blank the laser. 5.4V->830 mA which we are getting at the edges, and only getting around 400 mA in the center where the voltage is ˜3V.

In FIG. 8B, zooming in on the dither at the edges shows the frequency occurring at ˜70 kHz (scope is set at 20 usec/div, and 7 periods occurring in 100 usec=14 usec period=70 kHz).

Preferably, the dither amplitude and bench temperature to get an ideal match to HITRAN when the phase of the laser modes dither a multiple of 2*PI so they uniformly cover the region between the modes.

While this invention has been particularly shown and described with references to preferred embodiments thereof, it will be understood by those skilled in the art that various changes in form and details may be made therein without departing from the scope of the invention encompassed by the appended claims.

What is claimed is:

1. A spectroscopy system comprising:
a tunable laser configured to generate a laser output beam, the tunable laser comprising:
a gain chip receiving an injection current and configured to generate amplified light in response to the injection current; and
an external cavity formed between a reflective surface of the gain chip and an external reflector, the external cavity comprising a wavelength-selective element configured to select a lasing wavelength, the external cavity defining cavity modes with a cavity mode spacing; and
a modulation circuit configured to apply an oscillator drive signal to the injection current input of the gain chip, the oscillator drive signal having a frequency and amplitude sufficient to modulate an effective optical length of the external cavity, thereby shifting the cavity modes over a range sufficient to resolve narrow spectral features of a sample;
a detector configured to detect an absorption-induced signal from a sample illuminated by the laser output beam.

2. The spectroscopy system of claim 1, wherein the modulation circuit modulates the injection current such that the effective optical length of the external cavity varies over a range corresponding to a phase change of at least 2π radians at the lasing wavelength.

3. The spectroscopy system of claim 1, wherein the oscillator drive signal has a frequency greater than 1 kHz.

4. The spectroscopy system of claim 3, wherein the oscillator drive signal has a frequency greater than 1 MHz.

5. The spectroscopy system of claim 1, wherein the modulation circuit modulates the injection current at a frequency higher than a detection bandwidth of the detector, such that the detector averages over the modulation.

6. The spectroscopy system of claim 1, wherein the amplitude of the oscillator drive signal is sufficient to modulate the effective optical length of the external cavity by at least half of the wavelength of the laser light.

7. The spectroscopy system of claim 1, wherein the gain chip comprises a single angled facet edge-emitting gain chip.

8. The spectroscopy system of claim 1, wherein the wavelength-selective element comprises a tilt-tuned interference filter.

9. The spectroscopy system of claim 1, further comprising an angle control actuator configured to adjust an angle of the wavelength-selective element to tune the lasing wavelength over a scan range.

10. The spectroscopy system of claim 1, wherein the external reflector comprises a partially reflective mirror acting as an output coupler.

11. The spectroscopy system of claim 1, wherein the sample comprises a low-pressure gas.

12. A method for spectroscopy comprising:
generating laser light with a tunable laser comprising a gain chip and an external cavity, the external cavity comprising a wavelength-selective element configured to select a lasing wavelength, the external cavity defining cavity modes with a cavity mode spacing;
modulating an injection current to the gain chip with an oscillator drive signal having a frequency and amplitude sufficient to modulate an effective optical length of the external cavity, thereby shifting the cavity modes over a range sufficient to resolve narrow spectral features of a sample;
directing the laser light through a sample; and
detecting an absorption-induced signal from the sample.

13. The method of claim 12, wherein the modulation of the injection current causes the effective optical length of the external cavity to vary over a range corresponding to a phase change of at least 2π radians at the lasing wavelength.

14. The method of claim 12, wherein the oscillator drive signal has a frequency greater than 1 kHz.

15. The method of claim 14, wherein the oscillator drive signal has a frequency greater than 1 MHz.

16. The method of claim 12, further comprising tuning the lasing wavelength of the tunable laser by adjusting an angle of the wavelength-selective element relative to a beam path in the external cavity.

17. The method of claim 12, wherein the sample comprises a low-pressure gas.

18. The method of claim 12, wherein the modulation of the injection current causes the cavity modes to shift over at least one cavity mode spacing.

19. The method of claim 12, wherein the modulation of the injection current is at a frequency higher than a detection bandwidth of a detector used to detect the absorption-induced signal.

20. A modulation circuit for a tunable laser comprising:
an oscillator configured to generate an oscillator drive signal;
a driver configured to apply the oscillator drive signal to an injection current input of a gain chip of the tunable laser, the oscillator drive signal having a frequency and amplitude sufficient to modulate an effective optical length of an external cavity of the tunable laser, thereby shifting cavity modes of the tunable laser over a range sufficient to resolve narrow spectral features in spectroscopy applications.
